(19) United States
(12) Patent Application Publication
(10) Pub. No.: US 2024/0072160 A1
(43) Pub. Date: Feb. 29, 2024

(54) SEMICONDUCTOR DEVICE WITH TRENCH STRUCTURES AND METHOD FOR MANUFACTURING SAME

(71) Applicant: Monolithic Power Systems, Inc., Kirkland, WA (US)

(72) Inventors: Haifeng Yang, Shanghai (CN); Zhiyong Chen, Shanghai (CN); Vipindas Pala, San Jose, CA (US); Joel McGregor, Kirkland, WA (US); Zeqiang Yao, Kirkland, WA (US)

(21) Appl. No.: 18/454,362

(22) Filed: Aug. 23, 2023

(30) Foreign Application Priority Data
Aug. 31, 2022 (CN) 202211068769.8

(51) Int. Cl. H01L 29/66; H01L 21/762; H01L 29/08; H01L 29/16; H01L 29/808

(52) U.S. Cl. CPC H01L 29/66893; H01L 21/76237; H01L 29/0847; H01L 29/1608; H01L 29/808

(57) ABSTRACT

A semiconductor device is disclosed herein. The semiconductor device includes a silicon carbide substrate, trench structures, mesa structures, a first oxide layer, a conductive layer, a second oxide layer, a dielectric layer, and an insulation layer. The trench structures are formed on a surface of the silicon carbide substrate. Each trench structure has sidewalls and a bottom, and each respective mesa structure is formed between the respective adjacent trench structures. The first oxide layer is formed on the sidewalls of the trench structures. The conductive layer is formed on the bottom of the trench structures and on a top surface of each mesa structure. The second oxide layer is formed on the first oxide layer and the conductive layer. The dielectric layer is formed on the second oxide layer. The insulation layer is formed on the dielectric layer.

### CROSS-REFERENCE TO RELATED APPLICATIONS

This application claims priority to and the benefit of Chinese Patent Application 202211068769.8, filed on Aug. 31, 2022, which is incorporated herein by reference in its entirety.

### TECHNICAL FIELD

The present disclosure relates to a semiconductor device. More particularly, the present disclosure relates to a silicon carbide semiconductor device.

### BACKGROUND OF THE INVENTION

Silicon carbide has wide bandgap, high thermal conductivity, and large electron drift velocity. Accordingly, silicon carbide devices have better performance than silicon devices and can meet application requirements under difficult conditions, such as high temperature, high frequency, large power, and so on. Specifically, trench silicon carbide devices have even better capability to withstand high power.

However, due to the existence of carbon elements, silicon dangling bonds, carbon dangling bonds, and/or carbon-carbon bonds, trench silicon carbide devices have high-density interface state at the interface between silicon dioxide and silicon carbide substrate. Its interface state is two orders of magnitude higher than the interface state that silicon devices have at the interface between silicon dioxide and silicon substrate. Such high-density interface state causes delamination and malfunction of trench silicon carbide devices. Thus, trench silicon carbide devices with greater reliability are desired.

### SUMMARY OF THE INVENTION

According to an embodiment of the present disclosure, a semiconductor device is provided. The semiconductor device includes a silicon carbide substrate, trench structures, mesa structures, a first oxide layer, a conductive layer, a second oxide layer, a dielectric layer, and an insulation layer. The trench structures are formed on a surface of the silicon carbide substrate. Each trench structure has sidewalls and a bottom. Each respective mesa structure is formed between the respective adjacent trench structures. The first oxide layer is formed on the sidewalls of the trench structures. The conductive layer is formed on the bottom of the trench structures and on a top surface of each mesa structure. The second oxide layer is formed on the first oxide layer and the conductive layer. The dielectric layer is formed on the second oxide layer. The insulation layer is formed on the dielectric layer.

According to an embodiment of the present disclosure, a method for manufacturing a semiconductor device is provided. The method includes: providing a silicon carbide substrate; forming trench structures on a surface of the silicon carbide substrate, wherein each trench structure has sidewalls and a bottom; forming a first oxide layer on the sidewalls of the trench structures, wherein the first oxide layer comprises silicon dioxide; and performing thermal oxidation treatment.

According to an embodiment of the present disclosure, a semiconductor device is provided. The semiconductor device includes a silicon carbide substrate, source regions, a drain region, trench structures, mesa structures, channel implantation regions, gate regions, and a first oxide layer. The source regions are formed on a top surface of the silicon carbide substrate. The drain region is formed on a bottom layer of the silicon carbide substrate. The trench structures are formed on a surface of the silicon carbide substrate. Each trench structure has sidewalls and a bottom. Each respective mesa structure is formed between the respective adjacent trench structures. Each respective channel implantation region is formed in each respective mesa structure below the source region and located between the respective adjacent trench structures. The gate regions are formed on a top surface of the silicon carbide substrate. Each gate region surrounds the sidewalls and the bottom of each trench structure. The first oxide layer is formed on the sidewalls of the trench structures. Via a thermal oxidation treatment, oxygen flows through the first oxide layer and reaches to the silicon carbide substrate that is connected to the first oxide layer, and the silicon carbide substrate is oxidized and forms a thermal oxide layer.

### BRIEF DESCRIPTION OF THE DRAWINGS

The present disclosure can be further understood with reference to following detailed description and appended drawings, wherein like elements are provided with like reference numerals. These drawings are only for illustration purpose, thus may only show part of the devices and are not necessarily drawn to scale.

FIG. 1 is a schematic diagram of a cross-sectional view of a prior-art silicon carbide device having trench structures.

FIG. 2 is a schematic diagram of a semiconductor device with trench structures in accordance with an embodiment of the present disclosure.

FIG. 3 is a schematic diagram of a semiconductor device in accordance with an embodiment of the present disclosure.

FIG. 4 is a schematic diagram of a semiconductor device in accordance with another embodiment of the present disclosure.

FIG. 5 is a flowchart of a method for manufacturing a semiconductor device in accordance with an embodiment of the present disclosure.

FIGS. 6A-6F are schematic diagrams of a semiconductor device that is manufactured through the method as shown in FIG. 5 in accordance with an embodiment of the present disclosure.

FIG. 7 is a flowchart of a method for manufacturing a semiconductor device as shown in FIG. 4 in accordance with an embodiment of the present disclosure.

FIGS. 8A-8E are schematic diagrams of a semiconductor device that is manufactured through the method as shown in FIG. 7 in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

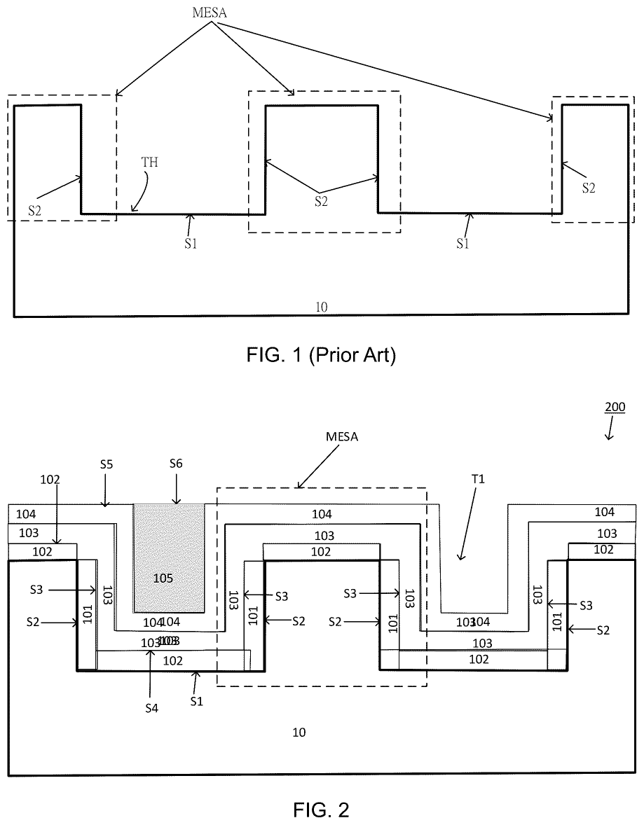

FIG. 1 is a schematic diagram of a cross-sectional view of a prior-art silicon carbide device having trench structures TH. As shown in FIG. 1, trench structures TH are formed on a silicon carbide substrate 10, for example, by an etching process. Each of the trench structures TH has a bottom and sidewalls. For instance, the surface S1 of the silicon carbide substrate 10 forms the bottom of the trench structures TH, and the surface S2 of the silicon carbide substrate 10 forms the sidewall of the trench structures TH. It should be noted that, although the surface S1 is perpendicular to the surface S2 as shown in FIG. 1, the sidewalls of the trench structures TH do not have to be perpendicular to the bottom of the trench structures TH. In other words, the trench structures TH could be any shape other than rectangular. In the present disclosure, a mesa structure MESA is referred to the silicon carbide substrate 10 that is between the adjacent trench structures TH.

FIG. 2 is a schematic diagram of a semiconductor device 200 with trench structures in accordance with an embodiment of the present disclosure. As shown in FIG. 2, the semiconductor device 200 includes a silicon carbide substrate 10, trench structures TH, a first oxide layer 101, a conductive layer 102, and a second oxide layer 103. In one embodiment as shown in FIG. 2, the trench structures TH are formed on the surface of the silicon carbide substrate 10, the trench structures TH have a bottom and sidewalls.

The first oxide layer 101 is formed on the sidewalls S2 of the trench structures TH and are directly on the surface of the silicon carbide substrate 10. Each first oxide layer 101 has a first surface and a second surface S3, and the first surface is directly in contact with the silicon carbide substrate 10. In one embodiment, the material of the first oxide layer 101 includes silicon dioxide. In one implementation, the thickness of the first oxide layer 101 is between 1300 Å-1700 Å. In another implementation, the thickness of the first oxide layer 101 is around 1500 Å.

The conductive layer 102 is formed on the bottom S1 of the trench structure TH and on the top surface of the mesa structures MESA. Each conductive layer 102 has a first surface and a second surface S4, and the first surface is directly in contact with the silicon carbide substrate 10 at the bottom S1 of the trench structures TH. In one embodiment, the conductive layer 102 is formed by depositing metal material. In another embodiment, the conductive layer 102 is formed by depositing nickel. In one embodiment, the thickness of the conductive layer 102 is between 300 Å-700 Å. In another embodiment, the thickness of the conductive layer 102 is around 500 Å.

The second oxide layer 103 is formed on the conductive layer 102 and the first oxide layer 101. It is worth noting that, in some embodiments, there are vias in the second oxide layer 103 configured to electrically connect the conductive layer 102 to an external device or component. In one embodiment, the material of the second oxide layer 103 includes silicon dioxide. In one implementation, the thickness of the second oxide layer 103 is between 600 Å-1300 Å. As a result, the second oxide layer 103 with such thickness effectively relieves the stress between the conductive layer 102 and a dielectric layer 104 caused by the change in temperature. It is worth noting that, when the thickness of the second oxide layer 103 is smaller, the effect on relieving the stress between the conductive layer 102 and the dielectric layer 104 will be not ideal, and delamination may occur in the surface between the conductive layer 102 and the second oxide layer 103, and delamination may occur in the surface between the second oxide layer 103 and the dielectric layer 104. In one embodiment, the first oxide layer 101 are formed before the conductive layer 102 is formed, and the second oxide layer 103 is formed after the conductive layer 102 is formed.

In one embodiment, the semiconductor device 200 further includes a dielectric layer 104 and an insulation layer 105. The dielectric layer 104 is formed on the second oxide layer 103. In one embodiment, the material of the dielectric layer 104 includes silicon nitride. In one embodiment, the thickness of the dielectric layer 104 is between 1700 Å-2900 Å. As a result, the stress between the dielectric layer 104 and the second oxide layer 103 is reduced, and thus preventing delamination occurred between the dielectric layer 104 and the second oxide layer 103 that is caused by the change in temperature. Thus, the reliability of the semiconductor device 200 is improved. It is worth noting that, when the thickness of the dielectric layer 104 is greater, the stress between the dielectric layer 104 and the second oxide layer 103 will increase, and delamination may occur in the surface between the second oxide layer 103 and the dielectric layer 104.

The insulation layer 105 is formed on the dielectric layer 104. In one embodiment, the material of the insulation layer 105 includes borophosphosilicate glass (BPSG). In the embodiment of FIG. 2, the dielectric layer 104 forms a concave region T1, and the insulation layer 105 is configured to fill the concave regions T1 to form a plane. That is, the top surface of the dielectric layer 104 (e.g., S5 as shown in FIG. 2) and the top surface of the insulation layer 105 are on the same plane (i.e., the top surface of the semiconductor device). It is worth noting that, for the purpose of illustrating the concave region T1, the insulation layer 105 is not shown in the concave region T1 in the right part of FIG. 2. In one embodiment, the thickness of the insulation layer 105 is between 11000 Å-12000 Å. In another embodiment, the thickness of the insulation layer 105 is around 11500 Å.

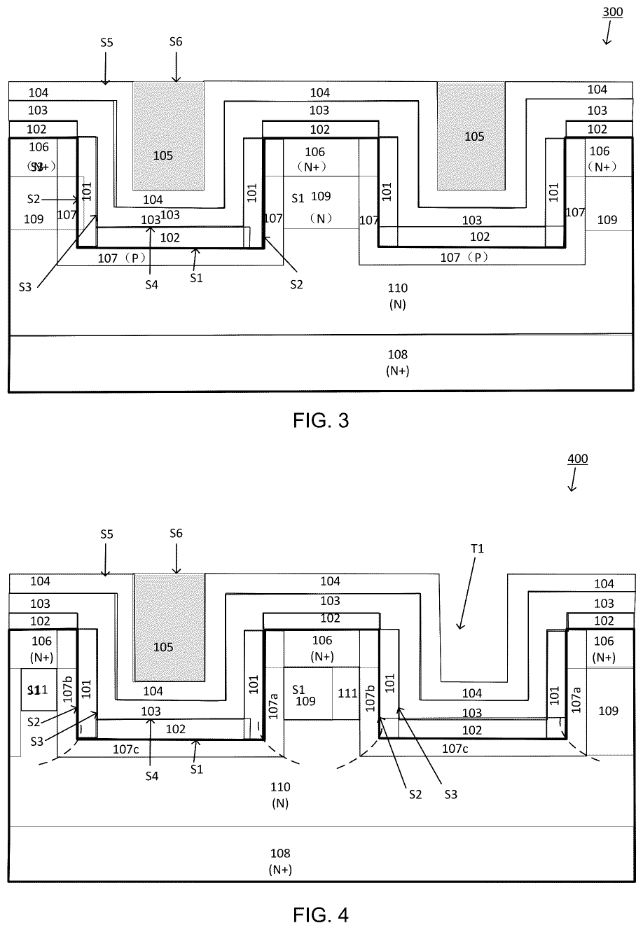

FIG. 3 is a schematic diagram of a semiconductor device 300 in accordance with an embodiment of the present disclosure. In this embodiment, the semiconductor device 300 further includes source regions 106, gate regions 107, a drain region 108, and channel implantation regions 109. The source regions 106 are formed on the top surface of the mesa structure MESA and are formed through ion implantation. In the embodiment of FIG. 3, the source regions 106 are of a first conductive type.

The gate regions 107 are formed on the top surface of the silicon carbide substrate 10. Each gate region 107 surrounds each trench structure TH. In the embodiment of FIG. 3, the gate regions 107 are of a second conductive type (e.g., P type).

The drain region 108 is formed on a bottom layer of the silicon carbide substrate 10. In the embodiment of FIG. 3, the drain region 108 is of the first conductive type (e.g., N+ type).

The channel implantation regions 109 are formed in the mesa structure MESA between the two adjacent gate regions 107. In the embodiment shown in FIG. 3, the channel implantation regions 109 are of the first conductive type (e.g., N type).

In one embodiment, the semiconductor device 300 includes a Junction Field Effect Transistor (JFET). When a voltage V_{DS} is applied between the drain region 108 and the source region 106 of the JFET and zero voltage is applied to the gate regions 107, the JFET is conducted via the channel formed between the source region 106 and the drain region 108. When a reversed bias applied across the gate regions 107 and the source regions 106 reaches a threshold voltage, i.e., the pinch-off voltage VP, the channel region of the JFET is pinched off by the depletion regions, and no current flows between the source and the drain of the JFET. In one embodiment, the channel implantation region 109 may advantageously allow easier and better control to the pinch off threshold voltage VP of the JFET.

In one embodiment, the semiconductor device 300 further includes a drift region 110. The drift region 110 is formed in the silicon carbide substrate 10 between the channel implantation regions 109 and the drain region 108. In the embodiment of FIG. 3, the drift region 110 is of the first conductive type (e.g., N type), and the doping concentration of the drift region 110 is less than the doping concentration of the drain region 108.

FIG. 4 is a schematic diagram of a semiconductor device 400 in accordance with another embodiment of the present disclosure. In the semiconductor device 400, the gate region includes a first gate region 107a, a second gate region 107b, a third gate region 107c, and a gate extension region 111. The first gate region 107a is formed at a first side of the mesa structure MESA, the second gate region 107b is formed at a second side of the mesa structure MESA, and the third gate region 107c is formed in the silicon carbide substrate 10 that is below the trench structure TH. In one embodiment, the first gate region 107a and the second gate region 107b are formed through angled ion implantation at the same time, and the third gate region 107c is formed through vertical ion implantation.

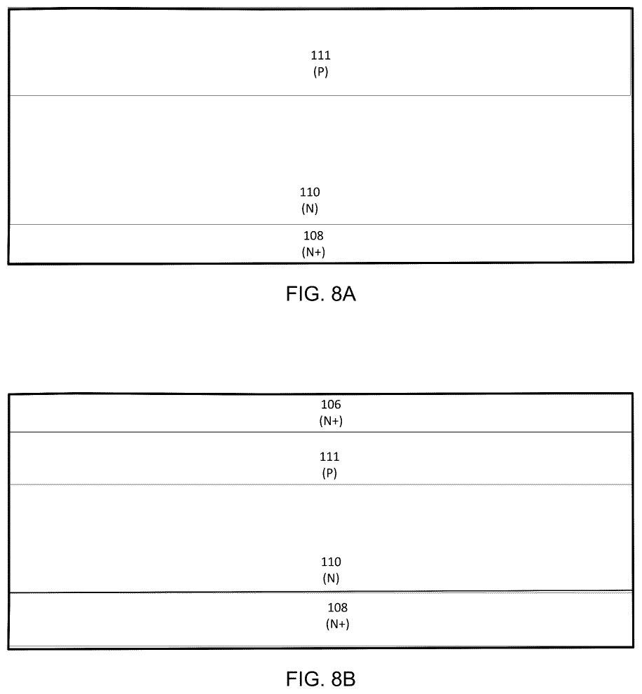

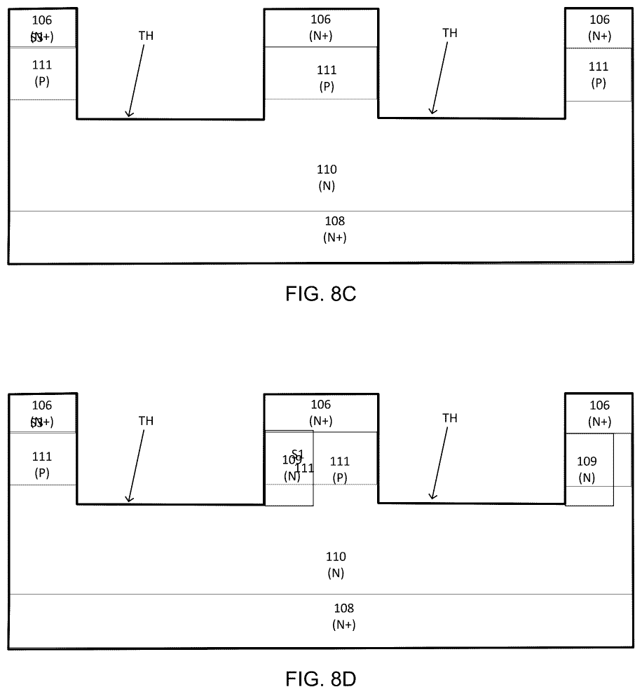

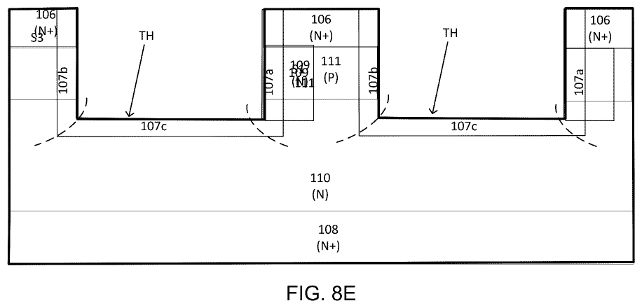

The gate extension region 111 is formed in the mesa structure MESA and below the source region 106. The gate extension region 111 is connected to the gate region 107 and located between the connected gate region 107 and the channel implantation region 109. Specifically, the gate extension region 111 is located between the second gate region 107b and the channel implantation region 109. The gate extension region 111 and the second gate region 107b are both of the second conductive type, and the doping concentration of the gate extension region 111 is less than the doping concentration of the second gate region 107b. In some embodiments, the gate extension region 111 is configured for controlling the width of the channel of the JFET. It is worth noting that, although in FIG. 4 and FIG. 8E the gate regions 107a, 107b, and 107c are divided by the dashed lines, there are physical overlaps between them.

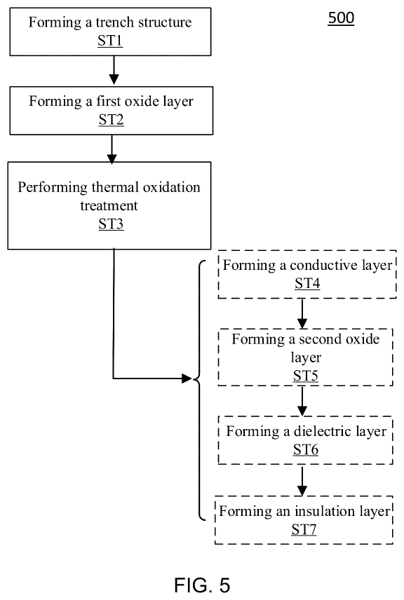

FIG. 5 is a flowchart of a method 500 for manufacturing a semiconductor device in accordance with an embodiment of the present disclosure. In one embodiment, the method 500 includes steps ST1-ST3.

At the step ST1, the trench structures TH are formed on the silicon carbide substrate 10. In some embodiments, the method 500 further includes providing the silicon carbide substrate 10 before performing the step ST1.

At the step ST2, the first oxide layer 101 is formed.

At the step ST3, a thermal oxide layer is formed on the surface of the silicon carbide substrate 10 by performing thermal oxidation treatment.

In one embodiment, the method 500 further includes steps ST4-ST7 for forming a silicon carbide device.

At the step ST4, the conductive layer 102 is formed.

At the step ST5, the second oxide layer 103 is formed.

At the step ST6, the dielectric layer 104 is formed.

At the step ST7, the insulation layer 105 is formed.

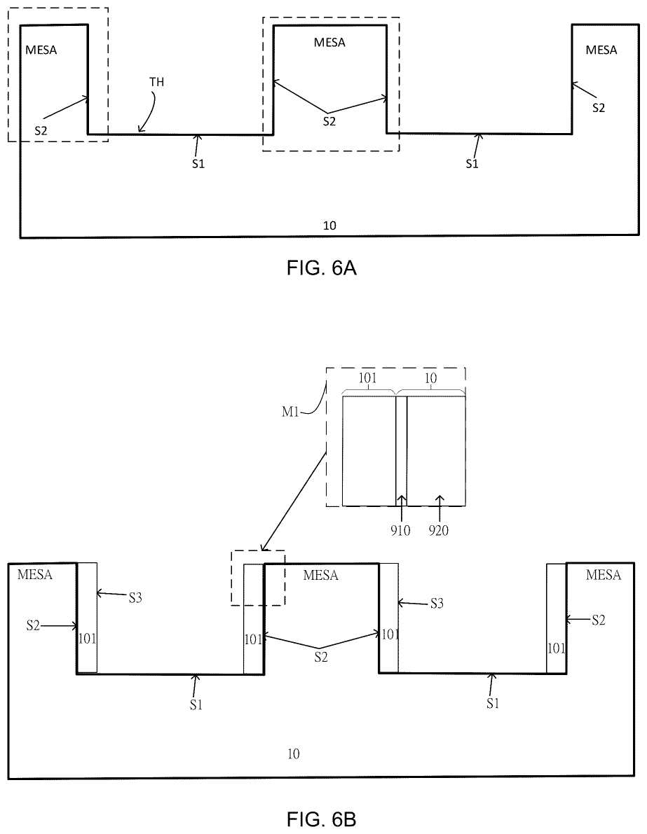

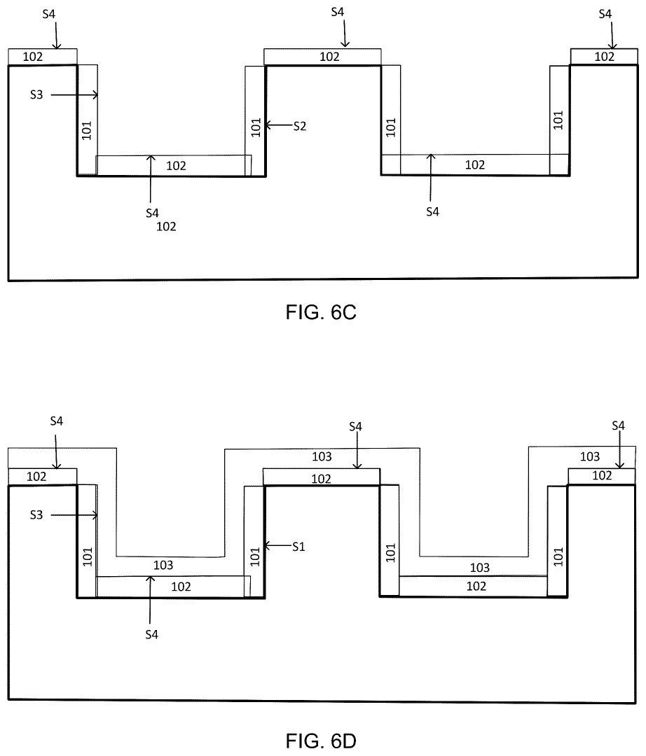

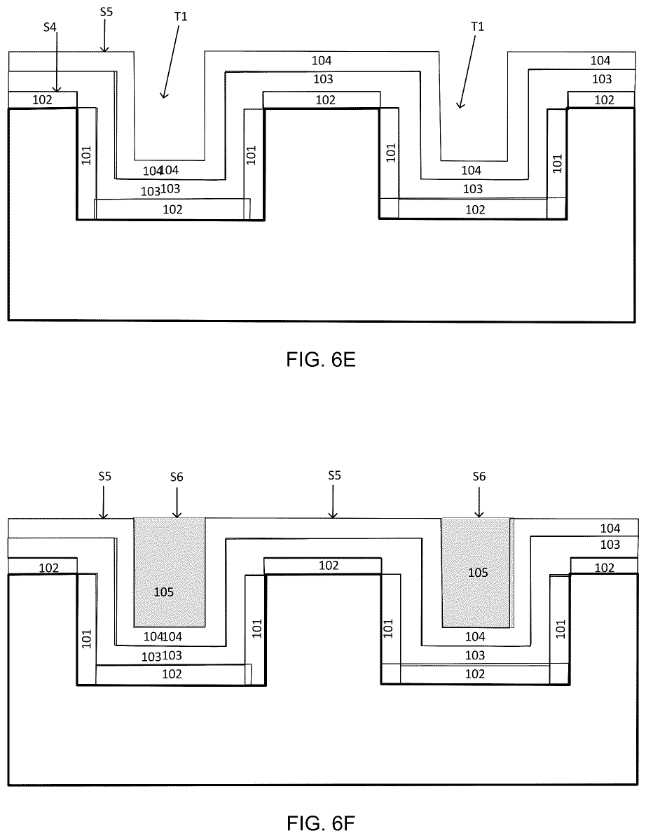

FIGS. 6A-6F are schematic diagrams for illustrating the method for manufacturing a semiconductor device with trench structures in accordance with an embodiment of the present disclosure.

With reference to FIG. 6A, trench structures TH are formed on the silicon carbide substrate 10. In one embodiment, an etching process is performed to etch the trench structures TH on the silicon carbide substrate 10. In one embodiment, a dry etching process is performed. Each trench structure TH includes the bottom S1 and the sidewalls S2 that are perpendicular to the bottom S1.

With reference to FIG. 6B, a first oxide layer 101 is formed on the sidewalls of the trench structures. In one embodiment, the first oxide layer 101 is formed through chemical vapor deposition (CVD). The material of the first oxide layer 101 includes silicon dioxide. In one embodiment, the thickness of the first oxide layer 101 is between 1300 Å-1700 Å. In another embodiment, the thickness of the first oxide layer 101 is around 1500 Å. It is worth noting that the first oxide layer 101 is formed by lithography process, including multiple process using photoresist and photomask. In the embodiment of FIG. 6B, after the lithography process, the first oxide layer 101 is formed on the sidewalls S2 of the trench structures TH.

Still with reference to FIG. 6B, a thermal oxidation treatment is performed. Specifically, the oxygen flows through the first oxide layer 101 and reaches to the silicon carbide substrate 10, and thus the silicon carbide substrate 10 that is connected to the first oxide layer 101 is oxidized and forms the thermal oxide layer. The thermal oxide layer is formed between the first oxide layer 101 and the silicon carbide substrate 10. In some embodiments, the thermal oxidation treatment is performed under 1100° C.-1200° C. In such range, the reaction rate of oxidation is faster. A block M1 shows an enlarged view of the semiconductor device. In some embodiments, after a thermal oxidation treatment is performed, the surface of the silicon carbide substrate 10 is oxidized to become silicon dioxide and transform into a thermal oxide layer 910. The thermal oxide layer 910 is connected to and formed between the first oxide layer 101 and the portion 920. In some embodiments, the thermal oxide layer 910 is a thin film formed on the surface of the silicon carbide substrate 10.

In one embodiment, compared with the first oxide layer 101, the thermal oxide layer has higher density and smaller thickness. Thus, due to the higher density of the thermal oxide layer, the viscosity between the first oxide layer 101 and the silicon carbide substrate 10 increases, and therefore delamination between them may be avoided.

With reference to FIG. 6C, conductive layer 102 is formed. In one embodiment, the conductive layer 102 is formed through deposition. In one embodiment, the conductive layer 102 is formed through depositing metal material, e.g., nickel. In one embodiment, a metal layer is deposited on the structure shown in FIG. 6B. The metal layer reacts with the silicon carbide substrate 10 to form metal silicide. In one embodiment of FIG. 6C, the conductive layer 102 is formed on the bottom of the trench structure TH to electrically connect to the gate regions. In one embodiment of FIG. 6C, the conductive layer 102 is formed on the mesa structure MESA to electrically connect to the source regions. Each conductive layer 102 includes first surface and second surface. The bottom surface of the conductive layer 102 is in contact with the silicon carbide substrate 10.

With reference to FIG. 6D, a second oxide layer 103 is formed on the first oxide layer 101 and the conductive layer 102. In one embodiment, the second oxide layer 103 is formed through deposition. In one embodiment, the thickness of the second oxide layer 103 is between 600 Å-1300 Å. The second oxide layer 103 with such thickness may effectively relieve the stress between the conductive layer 102 and the later-formed dielectric layer 104 resulting from temperature change. It is worth noting that, when the thickness of the second oxide layer 103 is smaller, the second oxide layer 103 may not effectively relieve the stress between the conductive layer 102 and the dielectric layer 104 resulting from temperature change, and delamination may occur between the second oxide layer 103 and the conductive layer 102 and between the second oxide layer 103 and the dielectric layer 104.

With reference to FIG. 6E, the dielectric layer 104 is formed. In one embodiment, the dielectric layer 104 is deposited on the second oxide layer 103. In one embodiment, the thickness of the dielectric layer 104 is between 1700 Å-2900 Å. When the thickness of the dielectric layer 104 is in such range, the stress of the dielectric layer 104 resulting from temperature change is decreased, and the delamination between the dielectric layer 104 and the second oxide layer 103 due to the stress may be avoided. Thus, the semiconductor device 200 has greater reliability. It is worth noting that, when the thickness of the dielectric layer 104 is larger, the stress of the dielectric layer 104 resulting from temperature change becomes larger, and delamination may occur between the dielectric layer 104 and the second oxide layer 103. In some embodiments, the dielectric layer 104 forms the concave structure T1. In some embodiments, the dielectric layer 104 includes a surface S5.

With reference to FIG. 6F, the insulation layer 105 is formed. In one embodiment, the material of the insulation layer 105 has borophosphosilicate glass. In one embodiment, the insulation layer 105 is formed on the dielectric layer 104, and the insulation layer 105 includes the top surface S6. The insulation layer 105 is configured to fill the concave structure T1 to form a plane, and thus the top surface S6 of the insulation layer 105 and the surface S5 of the dielectric layer 104 are on the same plane. In one embodiment, the thickness of the insulation layer 105 is between 11000 Å-12000 Å. In another embodiment, the thickness of the insulation layer 105 is around 11500 Å.

It is worth noting that only essential steps are described above with reference to FIGS. 6A-6F to form a semiconductor device with trench structures TH. However, for persons having ordinary skills in the art, it is obvious that there may be additional steps to form the semiconductor device. Moreover, according to different types and structures of semiconductor device, including JFET, MOSFET, and IGBT, the method for manufacturing the semiconductor device may require different steps. It should be noted that these steps may be performed in any order.

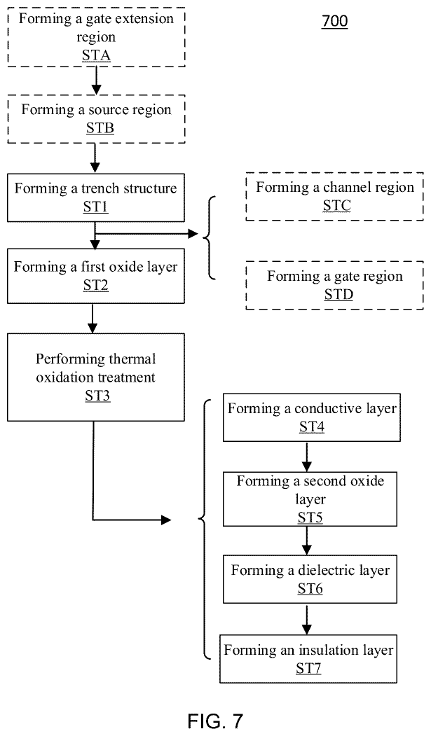

FIG. 7 is a flowchart of a method 700 for manufacturing a semiconductor device in accordance with an embodiment of the present disclosure. In this embodiment, compared with the method 500 shown in FIG. 5, the method 700 shown in FIG. 7 further includes steps STA-STD.

At the step STA, the gate extension region 111 is formed.

At the step STB, the source region 106 is formed.

At the step STC, the channel implantation region 109 is formed.

At the step STD, the gate region 107 is formed.

It is obvious to persons skilled the art that these steps could be performed in any order.

FIGS. 8A-8E are schematic diagrams of a semiconductor device that is manufactured through the method 700 as shown in FIG. 7 in accordance with an embodiment of the present disclosure.

With reference to FIG. 8A, the gate extension region 111 is formed. For illustration of FIG. 8A, the gate extension region 111 is formed on the silicon carbide substrate 10, and the silicon carbide substrate 10 includes a substrate 108 and the drift region 110. The substrate 108 is of the first conductive type (e.g., N type) for forming the drain region 108 on the bottom layer of the semiconductor device 400, the drift region 110 is of the first conductive type (e.g., N type), and the doping concentration (e.g., N) of the drift region 110 is less than the doping concentration (e.g., N+) of the substrate 108. In one embodiment, the drift region 110 is formed through growing an epitaxial layer on the substrate 108. In one embodiment, ion implantation is performed to form the gate extension region 111 on the top surface of the drift region 110. In the embodiment of FIG. 8A, the gate extension region 111 is of the second conductive type (e.g., P type) and is above the drift region 110.

With reference to FIG. 8B, the source region 106 is formed. In one embodiment, the source region 106 is formed on the gate extension region 111 through ion implantation, and the source region 106 is of the first conductive type (e.g., N type). In the embodiment of FIG. 8B, the drain region 108 is of the first conductive type (e.g., N type).

With reference to FIG. 8C, the trench structures TH are formed. In one embodiment, an etching method is performed to etch the trench structures TH on the source region 106, the gate extension region 111, and the drift region 110. In the embodiment of FIG. 8C, a dry etching process is performed to etch the trench structures TH.

With reference to FIG. 8D, the channel implantation regions 109 are formed. In the embodiment of FIG. 8D, the N-type channel implantation regions 109 are formed through ion implantation.

With reference to FIG. 8E, the gate region is formed through ion implantation. In the embodiment of FIG. 8E, the gate region includes the first gate region 107a, the second gate region 107b, and the third gate region 107c. In one embodiment, the first gate region 107a and the second gate region 107b are formed through angled ion implantation at the same time. The third gate region 107c is formed through vertical ion implantation.

It is worth noting that FIG. 7 merely shows essential steps for forming the semiconductor device 400. The manufacturing process of silicon carbide devices are complicated, and the method 700 may further include steps that are known to those having ordinary skill in the art. Additional process may be included in the method 700. For example, annealing process and subsequent metal interconnection processes are necessary for connecting the source region 106, the drain region 108, and the gate region 107 of the semiconductor device 400 to external device(s). In one embodiment, multiple fast annealing processes are performed. For example, a first fast annealing and a second fast annealing are performed. The first fast annealing process is performed under 600° C. −700° C. for around 1 minute, and the second fast annealing process is performed under 1050° C. for around 3 minutes.

In the present disclosure, via the thermal oxidation treatment, the thermal oxide layer is formed on the surface of the silicon carbide substrate 10 that is connected to the first oxide layer 101. Specifically, the oxygen flows through the first oxide layer 101 and reaches to the silicon carbide substrate 10, and thus the silicon carbide substrate 10 that is connected to the first oxide layer 101 is oxidized and forms the thermal oxide layer. By the thermal oxide layer, the viscosity between the first oxide layer 101 and the silicon carbide substrate 10 increases, and the delamination may be avoided. In addition, by adjusting the thickness of the second oxide layer 103 and the thickness of the dielectric layer 104, the effect on relieving stress resulting from temperature change may be further improved. Therefore, delamination may be avoided, and the semiconductor devices of the present disclosure have great reliability.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

What is claimed is:

1. A semiconductor device, comprising:
a silicon carbide substrate;
a plurality of trench structures formed on a surface of the silicon carbide substrate, wherein each trench structure has sidewalls and a bottom;
a plurality of mesa structures, wherein each respective mesa structure of the plurality of mesa structures is formed between the respective adjacent trench structures;
a first oxide layer formed on the sidewalls of the trench structures;
a conductive layer formed on the bottom of the trench structures and on a top surface of each of the plurality of mesa structures;
a second oxide layer formed on the first oxide layer and the conductive layer;
a dielectric layer formed on the second oxide layer; and
an insulation layer formed on the dielectric layer.

2. The semiconductor device of claim 1, further comprising:
a thermal oxide layer formed, via a thermal oxidation treatment, between the first oxide layer and the silicon carbide substrate.

3. The semiconductor device of claim 1, wherein a thickness of the second oxide layer is between 600 Å-1300 Å.

4. The semiconductor device of claim 1, wherein a thickness of the dielectric layer is between 1700 Å-2900 Å.

5. The semiconductor device of claim 1, further comprising:
a plurality of source regions formed on a top surface of the mesa structures;
a plurality of gate regions formed on a top surface of the silicon carbide substrate, wherein each gate region surrounds the sidewalls and the bottom of each trench structure;
a drain region formed on a bottom layer of the silicon carbide substrate; and
a plurality of channel implantation regions, wherein each respective channel implantation region is formed in each respective mesa structure and formed between the respective adjacent gate regions that surround the respective adjacent trench structure.

6. The semiconductor device of claim 5, further comprising:
a plurality of gate extension regions formed in the mesa structures, wherein each gate extension region is formed below each source region and connected to the gate region, wherein the gate extension region is located between the connected gate region and the channel implantation region.

7. A method for manufacturing a semiconductor device, comprising:
providing a silicon carbide substrate;
forming a plurality of trench structures on a surface of the silicon carbide substrate, wherein each trench structure has sidewalls and a bottom;
forming a first oxide layer on the sidewalls of the trench structures, wherein the first oxide layer comprises silicon dioxide; and
performing thermal oxidation treatment.

8. The method of claim 7, wherein via the thermal oxidation treatment, oxygen flows through the first oxide layer and reaches to the silicon carbide substrate that is connected to the first oxide layer, and the silicon carbide substrate is oxidized and forms a thermal oxide layer.

9. The method of claim 7, further comprising:
forming a conductive layer by metal deposition process on the bottom of the trench structures and on a top surface of a plurality of mesa structures, wherein each respective mesa structure of the plurality of mesa structures is formed between the respective adjacent trench structures;
forming a second oxide layer on the first oxide layer and the conductive layer;
forming a dielectric layer on the second oxide layer; and
forming an insulation layer on the dielectric layer, wherein the insulation layer comprises borophosphosilicate glass.

10. The method of claim 7, wherein a thickness of the second oxide layer is between 600 Å-1300 Å.

11. The method of claim 7, wherein a thickness of the dielectric layer is between 1700 Å-2900 Å.

12. The method of claim 7, further comprising:
forming a plurality of channel implantation regions in a plurality of mesa structures, wherein each respective mesa structure of the plurality of mesa structures is formed between the respective adjacent trench structures;
forming a plurality of gate regions on a top surface of the silicon carbide substrate, wherein each gate region surrounds the sidewalls and the bottom of each trench structure;
forming a source region on a top surface of the mesa structures; and
forming a drain region on a bottom layer of the silicon carbide substrate.

13. The method of claim 12, further comprising:
forming a plurality of gate extension regions in a plurality of mesa structures, wherein each respective mesa structure of the plurality of mesa structures is formed between the respective adjacent trench structures, each gate extension region is formed below each source region and connected to the gate region, wherein the gate extension region is located between the connected gate region and the channel implantation region.

14. A semiconductor device, comprising:
a silicon carbide substrate;
a plurality of source regions formed on a top surface of the silicon carbide substrate;
a drain region formed on a bottom layer of the silicon carbide substrate;
a plurality of trench structures formed on a surface of the silicon carbide substrate, wherein each trench structure has sidewalls and a bottom;
a plurality of mesa structures, wherein each respective mesa structure of the plurality of mesa structures is formed between the respective adjacent trench structures;
a plurality of channel implantation regions, wherein each respective channel implantation region is formed in each respective mesa structure below the source region and located between the respective adjacent trench structures;
a plurality of gate regions formed on a top surface of the silicon carbide substrate, wherein each gate region surrounds the sidewalls and the bottom of each trench structure; and
a first oxide layer formed on the sidewalls of the trench structures;
wherein via a thermal oxidation treatment, oxygen flows through the first oxide layer and reaches to the silicon carbide substrate that is connected to the first oxide layer, and the silicon carbide substrate is oxidized and forms a thermal oxide layer.

15. The semiconductor device of claim 14, further comprising:
a conductive layer formed on the bottom of the trench structures and on a top surface of the source regions; and
a second oxide layer formed on the first oxide layer and the conductive layer.

16. The semiconductor device of claim 15, further comprising:
a dielectric layer formed on the second oxide layer.

17. The semiconductor device of claim 16, further comprising:
an insulation layer formed on the dielectric layer.

18. The semiconductor device of claim 14, wherein a thickness of the second oxide layer is between 600 Å-1300 Å.

19. The semiconductor device of claim 14, wherein a thickness of the dielectric layer is between 1700 Å-2900 Å.

20. The semiconductor device of claim 14, further comprising:
a plurality of gate extension regions formed in the mesa structures, wherein each gate extension region is formed below each source region and connected to the gate region, wherein the gate extension region is located between the connected gate region and the channel implantation region.
